(19) United States
(12) Patent Application Publication
(10) Pub. No.: US 2026/0062791 A1
(43) Pub. Date: Mar. 5, 2026

(54) MASK ASSEMBLY MANUFACTURING APPARATUS

(71) Applicant: Samsung Display Co., Ltd., Yongin-si (KR)

(72) Inventors: SUCKHO KANG, Yongin-si (KR); WANSUB KIM, Yongin-si (KR); DAUN JO, Yongin-si (KR); JONGDAE LEE, Yongin-si (KR); WONYOUNG JANG, Yongin-si (KR); KYONGHO HONG, Yongin-si (KR)

(21) Appl. No.: 19/311,986

(22) Filed: Aug. 27, 2025

(30) Foreign Application Priority Data
Aug. 28, 2024 (KR) 10-2024-0115630

(51) Int. Cl. C23C 14/04

(52) U.S. Cl. CPC C23C 14/042

(57) ABSTRACT

Provided is a mask assembly manufacturing apparatus including a mask stage for seating thereon a mask frame defining an opening, a clamp unit at one side of the mask stage, and comprising first clamps arranged in a first direction and configured to clamp a first edge of a first mask sheet, and to position a second edge of the first mask sheet, which is opposite to the first edge, over the opening, a sensor configured to sense the second edge of the first mask sheet, and a controller configured to align the first mask sheet by adjusting the first clamps based on information regarding the second edge from the sensor.

### CROSS-REFERENCE TO RELATED APPLICATION

The present application claims priority to, and the benefit of, Korean Patent Application No. 10-2024-0115630, filed on Aug. 28, 2024, in the Korean Intellectual Property Office, the entire disclosure of which is incorporated herein by reference.

### BACKGROUND

### 1. Field

Embodiments of the present disclosure relate to a mask assembly manufacturing apparatus.

### 2. Description of the Related Art

Electronic devices based on mobility have been widely used. In addition to small-sized electronic devices, such as mobile phones, tablet personal computers (PCs), have also become widely used in recent years as portable electronic devices.

Such portable electronic devices may include a display device configured to provide visual information, such as images or videos, to a user in order to support various functions. Recently, as other components for driving display devices have been miniaturized, the proportion of display devices in electronic devices has been gradually increasing, and structures enabling the display devices to be bent at a corresponding angle from a flat state have also been developed.

An organic light-emitting display device may be manufactured using a vacuum deposition method in which an organic material, a metal used as an electrode, or the like is deposited onto a substrate in a vacuum atmosphere to form a thin film. The vacuum deposition method is performed by positioning a substrate, on which an organic thin film is to be formed, inside a vacuum chamber, bringing a mask having a pattern identical to that of the thin film or the like into close contact with the substrate, and depositing the organic material onto the substrate by evaporating or sublimating the organic material using a deposition source.

Such a mask is used repeatedly in deposition and cleaning processes to form organic thin films on a plurality of substrates, thereby maintaining the durability of the mask.

The aforementioned background technology is technical information possessed by the inventor for derivation of the present disclosure or acquired by the inventor during the derivation of the present disclosure, and is not necessarily prior art disclosed to the public before the application of the present disclosure.

### SUMMARY

Embodiments of the present disclosure are directed to providing a mask assembly manufacturing apparatus.

According to an aspect of the present disclosure, there is provided a mask assembly manufacturing apparatus including a mask stage for seating thereon a mask frame defining an opening, a clamp unit at one side of the mask stage, and including first clamps arranged in a first direction and configured to clamp a first edge of a first mask sheet, and to position a second edge of the first mask sheet, which is opposite to the first edge, over the opening, a sensor configured to sense the second edge of the first mask sheet, and a controller configured to align the first mask sheet by adjusting the first clamps based on information regarding the second edge from the sensor.

The clamp unit may further include second clamps arranged in a second direction, which is different from the first direction, and configured to clamp a third edge of the first mask sheet between the first edge and the second edge.

The controller may be further configured to align the first mask sheet by adjusting the first clamps in the second direction and maintaining positions of the second clamps in the first direction.

The controller may be further configured to move the clamp unit upwardly and downwardly.

One of the first clamps may be on a first imaginary line extending between adjacent deposition openings in the first mask sheet.

The controller may be further configured to adjust the first clamps based on a position of a point at which the second edge of the first mask sheet crosses the first imaginary line.

The clamp unit may be configured to place a second mask sheet adjacent to the first mask sheet while clamping the second mask sheet using second clamps.

The controller may be further configured to adjust the first clamps based on a separation distance between the second mask sheet and the second edge of the first mask sheet.

The mask assembly manufacturing apparatus may further include a welder configured to weld and connect the second edge of the first mask sheet to the second mask sheet.

The mask assembly manufacturing apparatus may further include a supporter positioned between the clamp unit and the opening of the mask frame.

According to another aspect of the present disclosure, there is provided a mask assembly manufacturing apparatus including a mask stage for seating thereon a mask frame defining an opening, a clamp unit at one side of the mask stage, and including first clamps arranged in a first direction and configured to clamp a first edge of a first mask sheet, a sensor configured to sense a second edge of the first mask sheet that is joined to a second mask sheet adjacent to the first mask sheet in a second direction, and a controller configured to apply a compressive force to the first mask sheet by adjusting the first clamps based on information regarding the second edge.

The controller may be further configured to detect a separation distance between the second mask sheet and the second edge of the first mask sheet as the information.

The controller may be further configured to apply the compressive force to the first mask sheet in the second direction by moving the first clamps in the second direction based on the separation distance.

The controller may be further configured to move one region of the first mask sheet toward the second mask sheet by moving the first clamps in the second direction based on the separation distance.

The first clamps may include a first-a clamp and a first-b clamp, wherein the controller is further configured to move the first-a clamp and the first-b clamp using a first point of the second edge corresponding to the first-a clamp and a second point of the second edge corresponding to the first-b clamp.

The first point may be on the second edge crossing a first imaginary line extending in the second direction and that passes through the first-a clamp, wherein the second point is on the second edge crossing another first imaginary line extending in the second direction and that passes through the first-b clamp.

The first imaginary line may extend between adjacent deposition openings in the first mask sheet.

The clamp unit may further include second clamps arranged in the second direction, and configured to clamp a third edge of the first mask sheet between the first edge and the second edge.

The controller may be further configured to align a position of the first mask sheet by adjusting the first clamps in the second direction while maintaining positions of the second clamps in the first direction.

The mask assembly manufacturing apparatus may further include a welder configured to weld and connect the second edge of the first mask sheet to the second mask sheet.

### BRIEF DESCRIPTION OF THE DRAWINGS

The drawings attached to the present specification illustrate preferred embodiments of the present disclosure, and serve to further understand the technical idea of the present disclosure together with the detailed description of the present disclosure to be described below, and thus, the present disclosure should not be understood as being limited only to the matters shown in these drawings in which:

FIG. 1 is a perspective view schematically illustrating a mask assembly manufacturing apparatus according to one or more embodiments of the present disclosure;

FIG. 2 is a plan view of the mask assembly manufacturing apparatus shown in FIG. 1;

FIG. 3 is a side cross-sectional view of the mask assembly manufacturing apparatus shown in FIG. 1;

FIG. 4 is a block diagram for describing an operational state of the controller according to one or more embodiments of the present disclosure;

FIG. 5 is a view illustrating the mask assembly manufacturing apparatus in a state before a clamp unit according to one or more embodiments of the present disclosure aligns mask sheets;

FIG. 6 is a view illustrating a state in which the mask sheets are aligned from the state shown in FIG. 5;

FIG. 7 is a view illustrating the mask assembly manufacturing apparatus in a process in which the clamp unit according to one or more embodiments of the present disclosure aligns the mask sheets.

FIG. 8 is a view illustrating a state in which the mask sheets are aligned from the state shown in FIG. 7;

FIG. 9 is a view illustrating a process in which a welder welds the mask sheets after the mask sheets are aligned;

FIG. 10 is a view schematically illustrating a state in which a deposition layer is deposited on a substrate using a mask assembly; and

FIG. 11 is a cross-sectional view illustrating one sub-pixel of an organic light-emitting display device in which an emissive layer is deposited on the substrate shown in FIG. 10.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing one or more embodiments corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

In the present specification, a first direction DR1, and a second direction DR2 that crosses the first direction DR1, are defined as substantially horizontal directions, and a third direction DR3 is defined as a vertical direction. In one or more embodiments of the present disclosure, the first direction DR1 may correspond to a width direction of a mask stage 100 or a mask frame MF, the second direction DR2 may correspond to a length direction of the mask stage 100 or the mask frame MF, and the third direction DR3 may correspond to a height and/or thickness direction of the mask stage 100 or the mask frame MF.

In the present specification, the expression “in a plan view” may refer to a state viewed from the third direction DR3.

In the present specification, a mask assembly may be an open mask, but is not limited thereto, and may be understood as encompassing various types of masks used for deposition in display or semiconductor manufacturing processes, such as fine metal masks (FMMs).

In the present specification, the mask assembly may be understood as a structure in which a plurality of mask sheets MS are coupled to the mask frame MF.

The mask frame MF may have a rectangular frame shape including short sides extending in the first direction DR1, and long sides extending in the second direction DR2 crossing the first direction DR1, but the shape of the mask frame MF is not limited thereto.

An opening may be defined in the mask frame MF depending on the frame shape of the mask frame MF. In a plan view, the opening may have a rectangular shape, but the shape of the opening is not limited thereto.

Side surfaces of the mask frame MF facing outward may include side surfaces extending in the first direction DR1, and side surfaces extending in the second direction DR2. These outward-facing side surfaces of the mask frame MF may be defined as outer side surfaces of the mask frame. The outer side surfaces of the mask frame MF may be defined as edges of the mask frame MF.

Inner side surfaces of the mask frame MF may be defined by side surfaces of the mask frame MF opposite to the outer side surfaces. The opening may be defined by the inner side surfaces of the mask frame MF.

The mask frame MF may include a metal material. For example, the mask frame MF may include Invar® (Invar® being a registered trademark of Aperam Alloys IMPHY Joint Stock Company) or stainless steel.

In the present specification, the plurality of mask sheets MS constituting the mask assembly are referred to as a first mask sheet MS1, a second mask sheet MS2, and a third mask sheet MS3. However, this is merely to indicate that a plurality of mask sheets MS may be provided for manufacturing the mask assembly, and it should not be construed that the number of mask sheets MS included in the mask assembly is limited to three. The mask sheets MS joined together to form the mask assembly may be two, or may be four or more.

In the present specification, the term “mask sheet MS” may be understood as a collective term referring to the first to third mask sheets MS1 to MS3.

The mask sheet MS may be placed on the mask frame MF. The mask sheet MS may have a plane defined by the first direction DR1 and the second direction DR2. The mask sheet MS may have a rectangular shape including sides extending in the first direction DR1 and sides extending in the second direction DR2, but the shape of the mask sheet MS is not limited thereto.

In the present specification, for convenience of description, the mask sheets MS that are sequentially positioned in a plan view from one side to another side of the mask frame MF in the second direction DR2 are referred to as the first mask sheet MS1, the second mask sheet MS2, and the third mask sheet MS3, respectively.

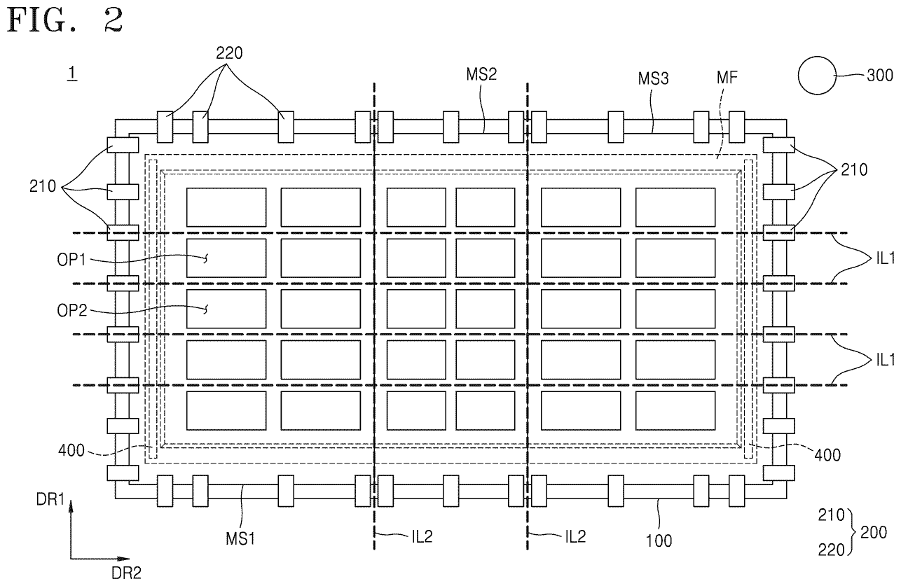

For example, the first mask sheet MS1 may be understood as a mask sheet placed at the leftmost side (based on FIG. 2) of the mask frame MF in a plan view, the third mask sheet MS3 may be understood as a mask sheet placed at the rightmost side (based on FIG. 2) of the mask frame MF in a plan view, and the second mask sheet MS2 may be understood as a mask sheet placed between the first mask sheet MS1 and the third mask sheet MS3.

In the present specification, the operation of a first clamp 210 and a control method of a controller 600 are described based on the first mask sheet MS1, but the first mask sheet MS1 may be understood as being replaceable with the third mask sheet MS3.

A plurality of deposition openings OP may be defined in the mask sheet MS. For example, the plurality of deposition openings OP may be arranged in the first direction DR1 and the second direction DR2. The deposition openings OP of the mask sheet MS may overlap the opening of the mask frame MF in a plan view. The deposition openings OP of the mask sheet MS may each have a rectangular shape that extends longer in the second direction DR2 than in the first direction DR1, but the shape of the deposition openings OP is not limited thereto.

For example, a first deposition opening OP1 and a second deposition opening OP2 may be formed in the mask sheet MS, and in the present specification, the first deposition opening OP1 and the second deposition opening OP2 are defined as deposition openings OP that are adjacent to each other in the first direction DR1.

To fabricate a large-area mask assembly, the plurality of mask sheets MS may be tension-coupled to the mask frame MF, and prior to tension-coupling the plurality of mask sheets MS to the mask frame MF, the first to third mask sheets MS1 to MS3 may be joined together to form a single plate-like mask sheet MS, which may then be tension-welded to the mask frame MF.

Prior to tension-coupling the mask sheet MS to the mask frame MF, a process of precisely aligning joint portions of the plurality of mask sheets MS may be suitable to ensure accurate joining of the plurality of mask sheets MS.

A mask assembly manufacturing apparatus 1 according to one or more embodiments of the present disclosure may precisely align the plurality of mask sheets MS using a clamp unit 200, and a detailed description thereof will be provided below.

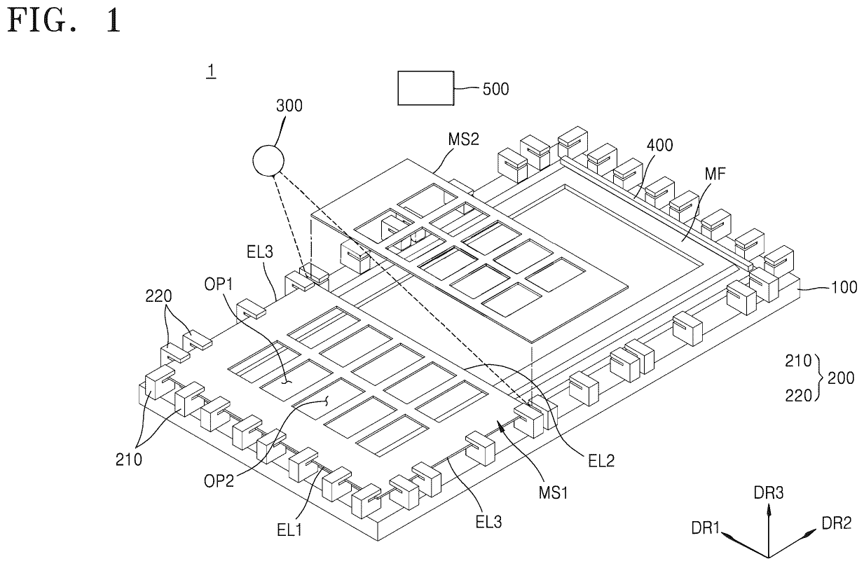

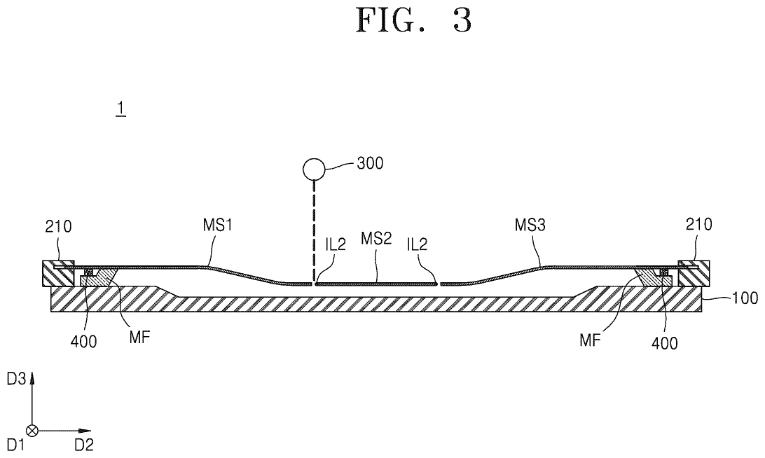

FIG. 1 is a perspective view schematically illustrating the mask assembly manufacturing apparatus 1 according to one or more embodiments of the present disclosure, FIG. 2 is a plan view of the mask assembly manufacturing apparatus 1 shown in FIG. 1, and FIG. 3 is a side cross-sectional view of the mask assembly manufacturing apparatus 1 shown in FIG. 1.

Referring to FIGS. 1 to 3, the mask assembly manufacturing apparatus 1 according to one or more embodiments of the present disclosure may include the mask stage 100, the clamp unit 200, a sensor (e.g., a sensing unit) 300, a supporter 400, a welder (e.g., a welding unit) 500, and the controller 600.

The mask stage 100 may support the mask frame MF. For example, the mask stage 100 may have the shape of an approximately rectangular flat plate, on which the mask frame MF may be positioned.

The mask sheets MS may be welded to the mask frame MF on the mask stage 100.

The mask stage 100 may provide a space in which the mask frame assembly is manufactured.

The clamp unit 200 may be positioned on one side of the mask stage 100.

For example, the clamp unit 200 may be positioned along the periphery of the mask stage 100, and in a plan view, the clamp unit 200 may be positioned above the mask stage 100, and may be spaced apart from the mask frame MF by a corresponding distance.

In one or more embodiments, the clamp unit 200 may be movably connected to the mask stage 100. For example, the clamp unit 200 may be connected to the mask stage 100, and may be movable in the second direction DR2 or in the third direction DR3.

In one or more embodiments, the clamp unit 200 and the mask stage 100 may be spaced apart by a corresponding distance.

For example, the clamp unit 200 may be spaced apart from the mask stage 100 by a corresponding distance, and may clamp edges of the first to third mask sheets MS1 to MS3 positioned above the mask stage 100.

The clamp unit 200 may be positioned on one side of the mask stage 100, and may clamp the mask sheet MS. The clamp unit 200 may include a plurality of first clamps 210 and a plurality of second clamps 220.

The plurality of first clamps 210 may be arranged in the first direction DR1, and may clamp a first edge EL1 of the first mask sheet MS1.

In the present specification, the term “first edge EL1” may be understood as one or more of the edges the first mask sheet MS1 that are parallel to the first direction DR1, and that overlap the mask frame MF or the mask stage 100 in a plan view.

The first edge EL1 may be defined as a short side of the mask sheet MS that is formed as a single plate when the first to third mask sheets MS1 to MS3 are joined together.

In the present specification, the term “second edge EL2” may be understood as one of the edges of the first mask sheet MS1 that is parallel to the first direction DR1 and that is joined to the second mask sheet MS2, and may also be understood as an edge positioned opposite to the first edge EL1.

In the present specification, the term “third edge EL3” may be understood as one or more of the edges of the first mask sheet MS1 that are parallel to the second direction DR2. The third edge EL3 may be defined as a long side of the mask sheet MS that is formed as a single plate when the first to third mask sheets MS1 to MS3 are joined together.

The plurality of first clamps 210 may be sequentially arranged in the first direction DR1 on a short-side region of the mask stage 100, and each of the first clamps 210 may be configured to receive a driving force from the outside, and may be movable in the second direction DR2 or in the third direction DR3.

Referring to FIG. 2, the first clamp 210 may be positioned on a first imaginary line IL1 that extends between adjacent deposition openings OP in the first mask sheet MS1.

In the present specification, the term “first imaginary line IL1” may be understood as an imaginary line that is parallel to, or that extends in, the second direction DR2, and that extends between adjacent deposition openings OP in the first mask sheet MS1.

For example, the first imaginary line IL1 may be understood as an imaginary line that extends in the second direction DR2 while passing through a region between the first deposition opening OP1 and the second deposition opening OP2.

The first clamp 210 may be linearly movable in the second direction DR2 along the first imaginary line IL1. For example, a central axis of movement of the first clamp 210 may be coaxial with the first imaginary line IL1.

Referring to FIG. 2, the central axis of movement of the first clamp 210 may be spaced apart from a region in which the deposition opening OP of the mask sheet MS is positioned.

For example, an imaginary line extending in the second direction DR2 while passing through the first clamp 210 may be spaced apart from the region in which the deposition opening OP of the mask sheet MS is positioned.

Accordingly, when the first clamp 210, which clamps the first edge EL1 of the first mask sheet MS1, moves in the second direction DR2 and applies a force to the first mask sheet MS1, a phenomenon in which a compressive force is transmitted to the deposition opening OP, thereby causing deformation of the shape of the deposition opening OP and reducing or preventing transmission of the compressive force to the second edge EL2, may be reduced.

Accordingly, when the first clamps 210 move in the second direction DR2 while clamping the first edge EL1, the second edge EL2 may also move in the second direction DR2 in accordance with the movement of the first clamps 210.

The first clamp 210 may clamp the first mask sheet MS1, and may apply a compressive force to the first mask sheet MS1 while moving in the second direction DR2 toward the second mask sheet MS2, but the first clamp 210 may be limited in applying a tensile force to the first mask sheet MS1.

The first clamps 210 may clamp the edge of either the first mask sheet MS1 or the third mask sheet MS3, and may be spaced apart from the second mask sheet MS2 by a corresponding distance.

The plurality of second clamps 220 may be arranged in the second direction DR2 that is different from the first direction DR1, and may clamp the third edge EL3 of the first mask sheet MS1.

The plurality of second clamps 220 may be sequentially arranged in the second direction DR2 on a long-side region of the mask stage 100, and each of the second clamps 220 may be configured to receive a driving force from the outside, and may be movable in the third direction DR3.

The plurality of first clamps 210 may grip the first edge EL1 of the first mask sheet MS1, and the plurality of second clamps 220 may grip the third edge EL3 of the first mask sheet MS1, so that the first clamps 210 and the second clamps 220 may position the second edge EL2 of the first mask sheet MS1 above the opening of the mask frame MF.

The plurality of first clamps 210 and the plurality of second clamps 220 may respectively concurrently or substantially simultaneously clamp the first edge EL1 and the third edge EL3 of the first mask sheet MS1, and the movement of the second clamps 220 may be limited while the first clamps 210 are moving.

For example, after clamping the first mask sheet MS1, the second clamps 220 may be limited from moving in the first direction DR1 and the second direction DR2.

Referring to FIG. 2, the clamp unit 200 may clamp the second mask sheet MS2 using the plurality of second clamps 220, and may place the second mask sheet MS2 adjacent to the first mask sheet MS1.

For example, the first mask sheet MS1 and the second mask sheet MS2 may be arranged adjacent to each other in the second direction DR2 with a second imaginary line IL2 interposed therebetween.

In the present specification, the term “second imaginary line IL2” may be understood as an imaginary line that is parallel to, or that extends in, the first direction DR1 and that passes through a region between the first mask sheet MS1 and the second mask sheet MS2, or through a region between the second mask sheet MS2 and the third mask sheet MS3.

However, the second imaginary line IL2 is not limited thereto, and may be understood as a boundary line at which the first mask sheet MS1 and the second mask sheet MS2 are joined.

However, the second imaginary line IL2 is not limited thereto, and may also be understood as an imaginary line that passes through one or more of the edges of the second mask sheet MS2, which are parallel to the first direction DR1 in a plan view and which extend in the first direction DR1.

A sensor 300 according to one or more embodiments of the present disclosure may sense the second edge EL2 of the first mask sheet MS1. In one or more embodiments, the sensor 300 may include a vision camera configured to obtain an image of the second edge EL2 of the first mask sheet MS1.

However, the sensor 300 is not limited thereto, and may include various devices capable of obtaining information on the second edge EL2 of the first mask sheet MS1 or gap information between the first mask sheet MS1 and the second mask sheet MS2. For example, the sensor 300 may include a laser sensor, an ultrasonic sensor, a line scan camera, a laser profile sensor, a spectrum camera, an infrared camera, or the like.

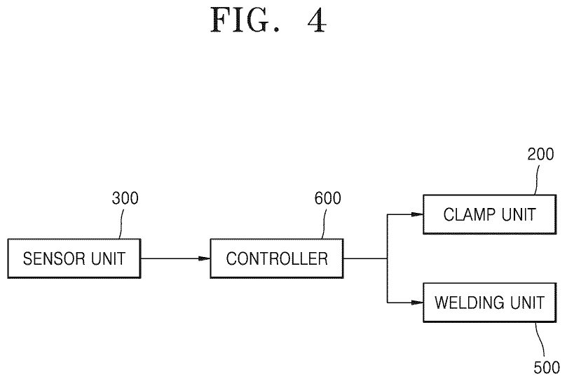

FIG. 4 is a block diagram for describing an operational state of the controller according to one or more embodiments of the present disclosure.

Referring to FIGS. 2 to 4, the sensor 300 may sense the second edge EL2 of the first mask sheet MS1, and may provide information on the second edge EL2 to the controller 600, and the controller 600 may align the first mask sheet MS1 by controlling the clamp unit 200 based on the information on the second edge EL2 sensed by the sensor 300.

The controller 600 may align the first mask sheet MS1 by adjusting the first clamps 210 in the second direction DR2 while maintaining positions of the second clamps 220 in the first direction DR1.

A method in which the controller 600 aligns the first mask sheet MS1 by controlling the operation of the clamp unit 200 based on the information on the second edge EL2 will be described in detail in the following description regarding the controller 600.

Referring again to FIGS. 1 to 3, the supporter 400 according to one or more embodiments of the present disclosure supports an edge side of the mask sheet MS, and may be positioned between the clamp unit 200 and the opening of the mask frame MF.

The supporter 400 may be formed in a rod shape extending in the first direction DR1. The supporter 400 may be positioned on an upper surface of the mask frame MF that faces the first mask sheet MS1 or the third mask sheet MS3. The supporter 400 may be spaced apart from the first clamp 210 by a corresponding distance, and one surface of the supporter 400 may be in surface contact with the first mask sheet MS1 or the third mask sheet MS3.

A stepped portion may be formed on a surface of the mask frame MF that faces the mask sheet MS, and a height of the mask frame MF in the third direction DR3 may vary according to the stepped portion.

For example, with reference to the stepped portion, one side of the mask frame MF adjacent to the first clamp 210 may have a relatively lower height than another side of the mask frame MF.

When the first clamp 210 clamps the edge of the first mask sheet MS1 that is supported while being in surface contact with another side of the mask frame MF, sagging of the first mask sheet MS1 may occur on one side of the mask frame MF due to the relatively lower height of the one side of the mask frame MF, which is positioned between the first clamp 210 and the another side of the mask frame MF.

The supporter 400 is positioned on the one side of the mask frame MF, and a height of the supporter 400 in the third direction DR3 may be equal to or similar to a height difference between the one side of the mask frame MF and the other side of the mask frame MF.

Accordingly, by positioning the supporter 400 in a portion where the height is reduced due to the stepped portion formed in the mask frame MF, the lower-height portion of the mask frame MF may be compensated for. Thus, sagging of the mask sheet MS at the stepped portion of the mask frame MF may be reduced.

Referring to FIG. 4, the welder 500 according to one or more embodiments of the present disclosure may weld and connect adjacent mask sheets MS to each other.

The welder 500 may weld the second edge EL2 of the first mask sheet MS1 to the second mask sheet MS2. For example, the welder 500 may join the second edge EL2 of the first mask sheet MS1 to the second mask sheet MS2 along the second imaginary line IL2.

The welder 500 may include various devices capable of fusing the edge of the first mask sheet MS1 to the edge of the second mask sheet MS2. For example, the welder 500 may include a laser welder, an ultrasonic welder, an electric resistance welder, a tungsten inert gas (TIG) welder, a metal inert gas (MIG) welder, a plasma welder, a micro welder, or the like.

The controller 600 according to one or more embodiments of the present disclosure may align the first mask sheet MS1 by adjusting the first clamps 210 based on the information on the second edge EL2 sensed by the sensor 300.

Hereinafter, a method of controlling the operations of the clamp unit 200 and the welder 500 based on sensing information sensed by the sensor 300 by the controller 600 will be described in detail.

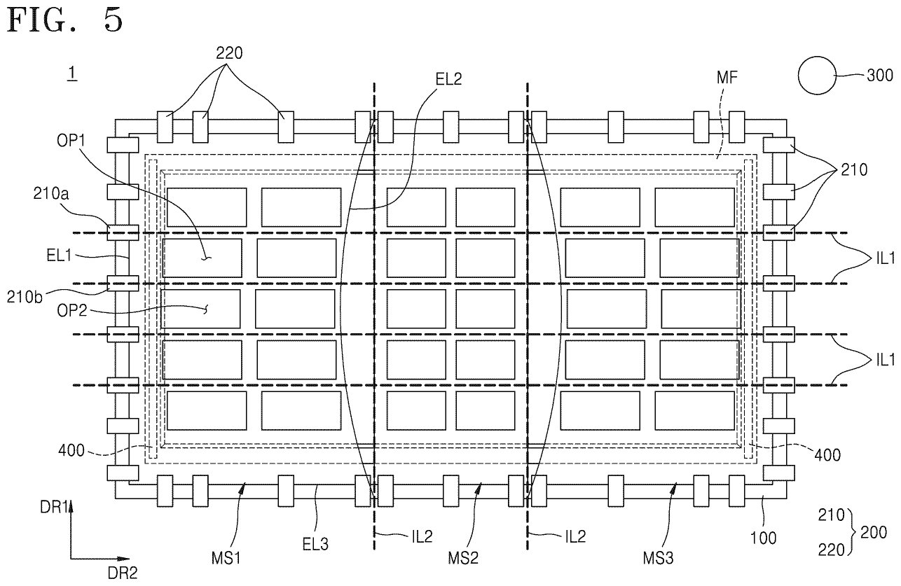

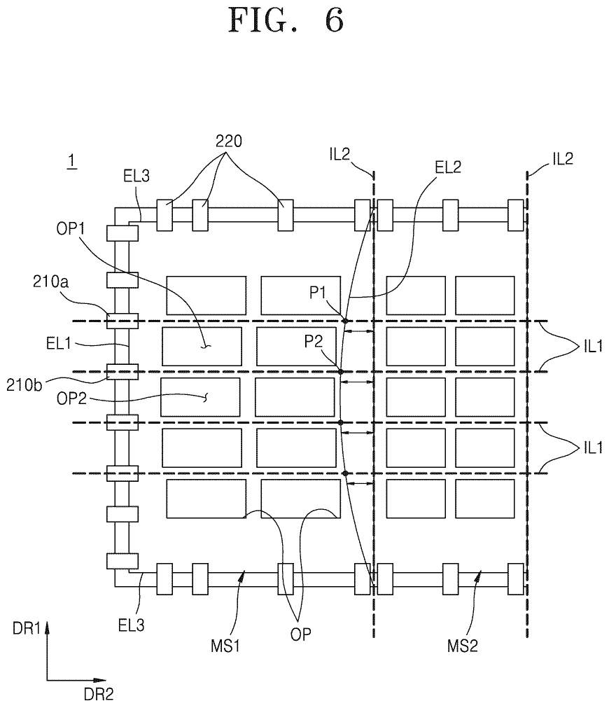

FIG. 5 is a view illustrating the mask assembly manufacturing apparatus 1 in a state before the clamp unit 200 according to one or more embodiments of the present disclosure aligns the mask sheets MS, and FIG. 6 is a view illustrating a state in which the mask sheets MS are aligned from the state shown in FIG. 5.

Referring to FIGS. 3, 5, and 6, when the first mask sheet MS1 is seated on an upper portion of the mask frame MF, one side of the first mask sheet MS1 may sag toward the opening of the mask frame MF due to a weight of the first mask sheet MS1.

The side of the first edge EL1 of the first mask sheet MS1 may be supported at a corresponding height by the first clamps 210, by the supporter 400, or by one surface of the mask frame MF, whereas the second edge EL2 of the first mask sheet MS1 is positioned above the opening of the mask frame MF, and may sag downwardly relative to the first edge EL1. As the second edge EL2 of the first mask sheet MS1 sags downwardly relative to the first edge EL1, the second edge EL2 may be pulled toward the first edge EL1 when the first mask sheet MS1 is viewed from the front. Accordingly, the second edge EL2 may be spaced apart from the second imaginary line IL2 or the edge of the second mask sheet MS2 by a corresponding distance.

In this state, when the first mask sheet MS1 and the second mask sheet MS2 are welded and connected to each other, a step difference may occur at the boundary between the first mask sheet MS1 and the second mask sheet MS2, which may reduce the precision of the process.

In the present specification, a first-a clamp 210a and a first-b clamp 210b may be understood as any two clamps among the plurality of first clamps 210, and a first point P1 may be understood as a point on the second edge EL2 that crosses the first imaginary line IL1 passing through the first-a clamp 210a.

In some embodiments, a second point P2 may be understood as a point on the second edge EL2 that crosses the first imaginary line (e.g., another first imaginary line) IL1 passing through the first-b clamp 210b.

The controller 600 may obtain information on the second edge EL2 from the sensor 300, or may detect the information on the second edge EL2 based on sensing information provided from the sensor 300.

In the present specification, the “information on the second edge EL2” may be understood not only as an optical or non-optical image of the second edge EL2, but also as information, such as information on a position of the second edge EL2 detected using the image of the second edge EL2.

For example, the information on the second edge EL2 may be understood as a separation distance between the second edge EL2 and the second mask sheet MS2, a separation distance between the second edge EL2 and the second imaginary line IL2, or a separation distance between the second edge EL2 and a marker positioned in one region of the mask assembly manufacturing apparatus 1.

The controller 600 may detect, as the information on the second edge EL2, a separation distance between the edge of the second mask sheet MS2 facing the first mask sheet MS1 and the second edge EL2 of the first mask sheet MS1.

For example, the controller 600 may obtain an image of the second edge EL2 and image information of the second mask sheet MS2 from the sensor 300, and may detect a separation distance between one point on the second edge EL2 and one point on the second mask sheet MS2, through both of which the first imaginary line IL1 passes.

In one or more embodiments, the controller 600 may detect the separation distance between the second edge EL2 and the second mask sheet MS2 as the information on the second edge EL2.

For example, the controller 600 may obtain an image of the second edge EL2 and image information of the second mask sheet MS2 from the sensor 300, and may detect a separation distance between the first point P1 and the edge of the second mask sheet MS2 along the first imaginary line IL1 passing through the first point P1, and a separation distance between the second point P2 and the edge of the second mask sheet MS2 along the (other) first imaginary line IL1 passing through the second point P2.

In one or more embodiments, the controller 600 may detect the separation distance between the second edge EL2 and the second imaginary line IL2 as the information on the second edge EL2.

For example, the controller 600 may obtain an image of the second edge EL2 and information on the second imaginary line IL2 from the sensor 300, and may detect a separation distance between the first point P1 and the second imaginary line IL2 along the first imaginary line IL1 passing through the first point P1, and a separation distance between the second point P2 and the second imaginary line IL2 along the (other) first imaginary line IL1 passing through the second point P2.

In one or more embodiments, the controller 600 may detect the separation distance between the second edge EL2 and the marker positioned in one region of the mask assembly manufacturing apparatus 1 as the information on the second edge EL2.

For example, the controller 600 may obtain an image of the second edge EL2 and information on the marker from the sensor 300, and may detect a separation distance between the first point P1 and the marker, and a separation distance between the second point P2 and the marker.

Hereinafter, a process in which the controller 600 aligns the first mask sheet MS1 by controlling the driving of the first clamp 210 using the information on the second edge EL2 will be described.

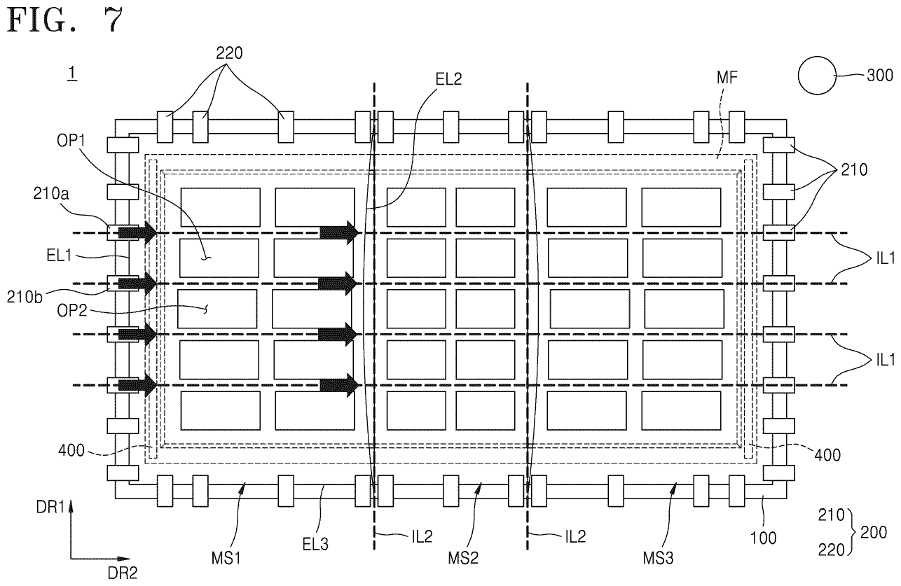

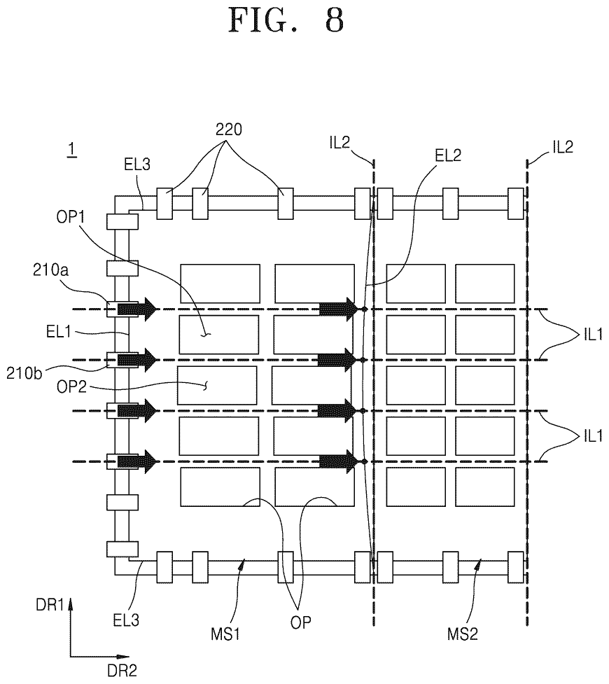

FIG. 7 is a view illustrating the mask assembly manufacturing apparatus 1 in a process in which the clamp unit 200 according to one or more embodiments of the present disclosure aligns the mask sheets MS, and FIG. 8 is a view illustrating a state in which the mask sheets MS are aligned from the state shown in FIG. 7.

Referring to FIGS. 4, 7, and 8, the controller 600 may control the driving of the first clamp 210 using the information on the second edge EL2.

In one or more embodiments, when the separation distance between the second edge EL2 and the second mask sheet MS2 exceeds a corresponding distance, the controller 600 may move the first clamps 210 in the second direction DR2 to move one region of the first mask sheet MS1 in a direction toward the second mask sheet MS2.

For example, when a separation distance between the first point P1 and the second mask sheet MS2 is A (e.g., in μm), and a separation distance between the second point P2 and the second mask sheet MS2 is B (e.g., in μm), which is greater than A, the controller 600 may move the first-a clamp 210a by C (e.g., in μm) in the direction toward the second mask sheet MS2, and may move the first-b clamp 210b by D (e.g., in μm), which is greater than C, in the direction toward the second mask sheet MS2.

Accordingly, even when the second edge EL2 is spaced apart from the second mask sheet MS2 due to sagging of the first mask sheet MS1, the second edge EL2 may become adjacent to the second mask sheet MS2 as the first clamps 210 push the first edge EL1 toward the second mask sheet MS2.

In one or more embodiments, when the separation distance between the second edge EL2 and the second imaginary line IL2 exceeds a corresponding distance, the controller 600 may move the first clamps 210 in the second direction DR2 to move one region of the first mask sheet MS1 in the direction toward the second mask sheet MS2.

For example, when a separation distance between the first point P1 and the second imaginary line IL2 is A (μm), and a separation distance between the second point P2 and the second imaginary line IL2 is B (μm), which is greater than A, the controller 600 may move the first-a clamp 210a by C (μm) in the direction toward the second mask sheet MS2, and may move the first-b clamp 210b by D (μm), which is greater than C, in the direction toward the second mask sheet MS2.

Accordingly, even when the second edge EL2 is spaced apart from the second mask sheet MS2 due to sagging of the first mask sheet MS1, the second edge EL2 may become adjacent to the second mask sheet MS2 as the first clamps 210 push the first edge EL1 toward the second mask sheet MS2.

Even when the first clamps 210 move in the second direction DR2 and push the first edge EL1 toward the second mask sheet MS2, a driving force applied by the first clamps 210 to the first mask sheet MS1 may not be effectively transmitted to the second edge EL2 due to friction between the first mask sheet MS1 and the supporter 400, due to friction between the first mask sheet MS1 and the mask frame MF, or the like.

After the first clamps 210 move in response to a control signal from the controller 600 and push the first edge EL1 toward the second mask sheet MS2, the controller 600 may move the first clamps 210 and the second clamps 220 upwardly and then downwardly in the third direction DR3.

Accordingly, after the first clamps 210 push the first edge EL1 toward the second mask sheet MS2, the first mask sheet MS1 may be separated from the supporter 400 and the mask frame MF, thereby eliminating the friction between the first mask sheet MS1 and the supporter 400, the friction between the first mask sheet MS1 and the mask frame MF, or the like.

As a result, the driving force applied to the first edge EL1 by the first clamps 210 may be effectively transmitted to the second edge EL2, thereby allowing the second edge EL2 to move toward the second mask sheet MS2.

The controller 600 may move the first clamps 210 and the second clamps 220 upwardly and then downwardly in the third direction DR3, and may receive image information of the second edge EL2 again from the sensor 300 to re-detect information on the second edge EL2.

In one or more embodiments, when a separation distance between the re-detected second edge EL2 and the second mask sheet MS2 exceeds a corresponding distance, the controller 600 may control the driving of the first clamp 210 according to the method described above, and when the separation distance between the re-detected second edge EL2 and the second mask sheet MS2 is detected to be less than or equal to the corresponding distance, the controller 600 may stop the driving of the first clamp 210.

Hereinafter, a process in which the controller 600 controls the operation of the welder 500 after the first mask sheet MS1 is aligned will be described.

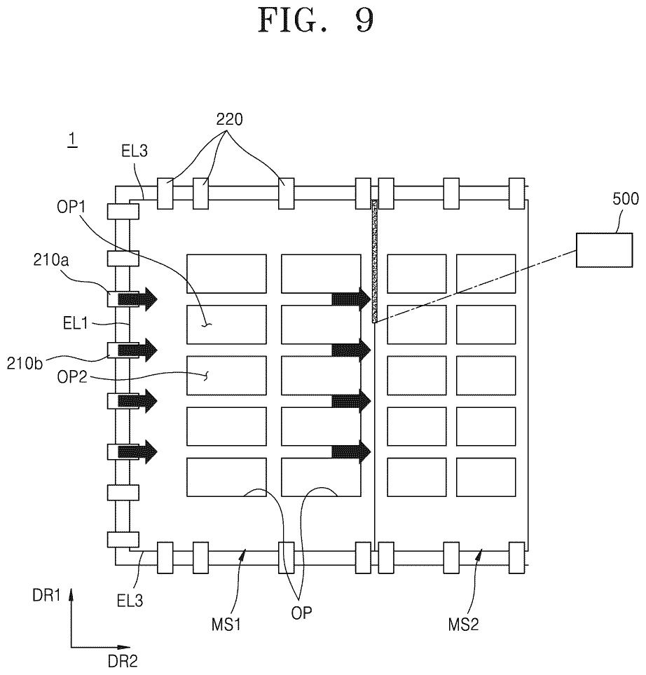

FIG. 9 is a view illustrating a process in which the welder 500 welds the mask sheets MS after the mask sheets MS are aligned.

Referring to FIG. 9, when the separation distance between the second edge EL2 and the second mask sheet MS2, the separation distance between the second edge EL2 and the second imaginary line IL2, or the separation distance between the second edge EL2 and the marker positioned in one region of the mask assembly manufacturing apparatus 1 is detected to be less than or equal to a corresponding value, the controller 600 may determine that the first mask sheet MS1 is aligned, and may fix the positions of the first clamps 210 and the second clamps 220.

When the controller 600 determines that the first mask sheet MS1 is aligned, the controller 600 may control the operation of the welder 500 to weld and connect the second edge EL2 of the first mask sheet MS1 to the second mask sheet MS2.

For example, the controller 600 may control the operation of the welder 500 so that the welder 500 welds the first mask sheet MS1 and the second mask sheet MS2 along the second imaginary line IL2.

Accordingly, the first mask sheet MS1 and the second mask sheet MS2, which are precisely aligned along a joint line, may be integrally joined.

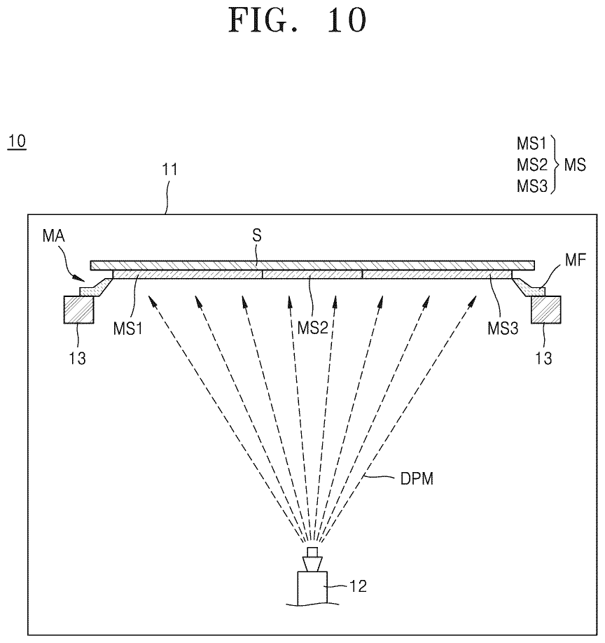

FIG. 10 is a schematic view illustrating a state in which a deposition layer is deposited on a substrate using a mask assembly.

Referring to FIG. 10, a deposition apparatus 10 may include a vacuum chamber 11 to deposit an organic emissive layer or an electrode of an organic light-emitting display device 1100 using a mask assembly MA.

A deposition source 12 is positioned inside the vacuum chamber 11, and the mask assembly MA may be installed above the deposition source 12. In this case, the mask assembly MA may include a plurality of mask sheets MS.

The mask sheets MS may be positioned on a mask frame MF, and a substrate S may be positioned above the mask sheets MS. In addition, a separate support member 13 for fixing the above components may be further included at an edge of the mask assembly MA.

The process of depositing a deposition material DPM onto the substrate S may be briefly described as follows.

First, the mask assembly MA may be fixed to the support member 13, and the substrate S for deposition may be positioned above the mask sheets MS.

Subsequently, the deposition material DPM may be emitted from the deposition source 12 positioned inside the vacuum chamber 11 toward the mask assembly MA. The deposition material DPM that passes through the mask sheets MS may be deposited on one surface of the substrate S. The deposition material DPM deposited on the substrate S may have a pattern (e.g., predetermined pattern) defined by deposition openings OP of the mask sheets MS.

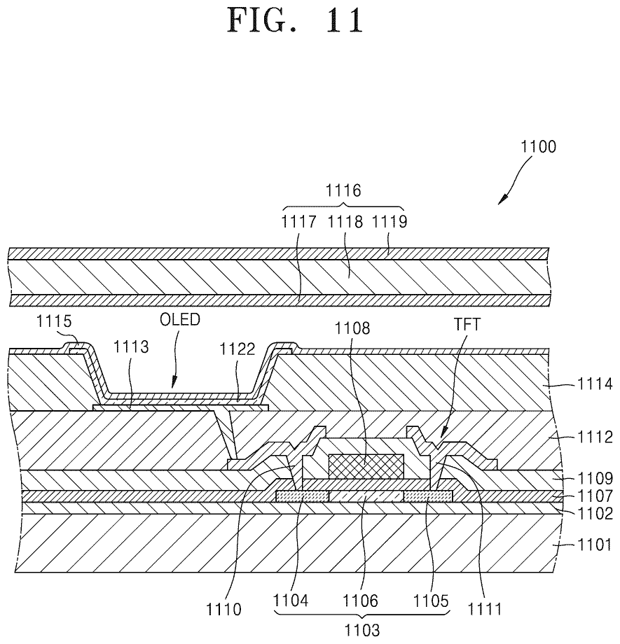

FIG. 11 is a cross-sectional view illustrating one sub-pixel of an organic light-emitting display device in which an emissive layer is deposited on the substrate shown in FIG. 10.

Referring to FIG. 11, the organic light-emitting display device 1100 may include a display substrate 1101. The display substrate 1101 may be fabricated using a flexible or rigid insulating material. The display substrate 1101 may be transparent, translucent, or opaque.

A barrier film 1102 may be formed on the display substrate 1101. The barrier film 1102 may cover an entire upper surface of the display substrate 1101. The barrier film 1102 may include an inorganic film or an organic film.

A thin-film transistor TFT may be formed on the barrier film 1102. A semiconductor active layer 1103 may be formed on the barrier film 1102. In the semiconductor active layer 1103, a source region 1104 and a drain region 1105 may be formed by doping N-type impurity ions or P-type impurity ions. A region between the source region 1104 and the drain region 1105 may be a channel region 1106 that is not doped with impurities.

A gate-insulating film 1107 may be deposited on the semiconductor active layer 1103. The gate-insulating film 1107 may include an inorganic film, such as silicon oxide, silicon nitride, or a metal oxide. The gate-insulating film 1107 may have a single-layer or multilayer structure.

A gate electrode 1108 may be formed in a region (e.g., predetermined region) on the gate-insulating film 1107. The gate electrode 1108 may include a single-layer or multilayer film of metals, such as gold (Au), silver (Ag), copper (Cu), nickel (Ni), platinum (Pt), palladium (Pd), aluminum (Al), molybdenum (Mo), or chromium (Cr). The gate electrode 1108 may also include an alloy, such as Al:Nd or Mo:W.

An interlayer insulating film 1109 may be formed on the gate electrode 1108. The interlayer insulating film 1109 may include an inorganic film, such as silicon oxide or silicon nitride, or an organic film.

A source electrode 1110 and a drain electrode 1111 may be formed on the interlayer insulating film 1109. For example, contact holes may be formed by selectively removing portions of the gate-insulating film 1107 and the interlayer insulating film 1109. Through the contact holes, the source electrode 1110 may be electrically connected to the source region 1104, and the drain electrode 1111 may be electrically connected to the drain region 1105.

A protective film 1112, such as a passivation film and/or a planarization film, may be formed on the source electrode 1110 and the drain electrode 1111. The protective film 1112 may include an inorganic film, such as silicon oxide or silicon nitride, or an organic film, such as acryl, polyimide, or benzocyclobutene (BCB).

An organic light-emitting element OLED may be formed above the thin-film transistor TFT. The organic light-emitting element OLED may be formed on the protective film 1112. The organic light-emitting element OLED may include a first electrode 1113, an intermediate layer 1122 including an organic emissive layer, and a second electrode 1115.

The intermediate layer 1122 may be formed in a region exposed by partially etching a pixel-defining film 1114 formed on the first electrode 1113. The intermediate layer 1122 may be formed through a deposition process. The intermediate layer 1122 may be patterned by a deposition material that is deposited through the deposition opening OP of the mask sheet MS of FIG. 1.

The pixel-defining film 1114 may cover portions of the protective film 1112 and the first electrode 1113. The pixel-defining film 1114 may define a light-emitting region of each sub-pixel by surrounding an edge of the first electrode 1113. The first electrode 1113 may be patterned for each sub-pixel. The pixel-defining film 1114 may include an organic film or an inorganic film. In addition, the pixel-defining film 1114 may include a single-layer film or a multilayer film.

The intermediate layer 1122 may be formed in a region on the first electrode 1113 that is exposed by partially etching the pixel-defining film 1114. The intermediate layer 1122 may be formed through a deposition process. The intermediate layer 1122 may be patterned by a deposition material deposited through a pattern hole of the mask sheet MS of FIG. 1.

The intermediate layer 1122 may include an organic emissive layer. In an optional example, the intermediate layer 1122 may include an organic emissive layer, and may further include at least one of a hole injection layer (HIL), a hole transport layer (HTL), an electron transport layer (ETL), and/or an electron injection layer (EIL). The present disclosure is not limited thereto, and the intermediate layer 1122 may include an organic emissive layer and various other functional layers.

The second electrode 1115 may be formed on the intermediate layer 1122. The second electrode 1115 may function as a cathode. The second electrode 1115 may include a transparent electrode or a reflective electrode. For example, when the second electrode 1115 is used as a transparent electrode, the second electrode 1115 may include a metal film and a transparent conductive film formed on the metal film. When the second electrode 1115 is used as a reflective electrode, the second electrode 1115 may include a metal film.

In one or more embodiments, a plurality of sub-pixels may be formed on the display substrate 1101, and each of the sub-pixels may implement a color of red, green, blue, or white. However, the present disclosure is not limited thereto.

A sealing substrate 1116 may be formed above the organic light-emitting element OLED. The sealing substrate 1116 may be formed to protect the intermediate layer 1122 and other thin films from external moisture, oxygen, and the like. The sealing substrate 1116 may include a rigid glass, a polymer resin, or a flexible film. The sealing substrate 1116 may be formed by alternately stacking organic films 1117 and 1119 and an inorganic film 1118 on the organic light-emitting element OLED. In one or more embodiments, the organic films 1117 and 1119 and the inorganic film 1118 may each include at least one layer.

Each of the embodiments described above is one or more embodiments that can be implemented independently, but it is also possible for the structures of each embodiment to be applied to other embodiments in a combined manner.

A mask assembly manufacturing apparatus according to embodiments of the present disclosure can precisely align welding lines of a plurality of mask sheets by adjusting edge positions of the mask sheets using a clamp unit.

However, the aspects obtainable through the present disclosure are not limited to the above-described aspects, and other aspects that are not mentioned will be clearly understood by those skilled in the art from the following description of the present disclosure.

The present disclosure has been described with reference to the examples illustrated in the drawings, but these are only examples. It will be understood by those skilled in the art that various modifications and equivalent other examples may be made. Accordingly, the true technical scope of the present disclosure is defined by the technical spirit of the appended claims.

The particular implementations shown and described herein are illustrative examples of the embodiments and are not intended to otherwise limit the scope of the embodiments in any way. In addition, no item or element is essential to the practice of the present disclosure unless the element is specifically described as “essential” or “critical.”

The use of the terms “a” and “an” and “the” and similar referents in the context of describing the present disclosure (especially in the context of the following claims) are to be construed to cover both the singular and the plural. Further, recitation of ranges of values herein is merely intended to serve as a shorthand method of referring individually to each separate value falling within the range, unless otherwise indicated herein, and each separate value is incorporated into the specification as if it were individually recited herein. Finally, operations of all methods described herein can be performed in any suitable order unless otherwise indicated herein or otherwise clearly contradicted by context. The present disclosure is not necessarily limited to the described order of the operations. The use of any and all examples, or exemplary terms provided herein, is intended merely to better illuminate the present disclosure and does not pose a limitation on the scope of the present disclosure unless otherwise claimed. Also, numerous modifications and adaptations will be readily apparent to one of ordinary skill in the art without departing from the spirit and scope of the present disclosure.

What is claimed is:

1. A mask assembly manufacturing apparatus comprising:
a mask stage for seating thereon a mask frame defining an opening;
a clamp unit at one side of the mask stage, and comprising first clamps arranged in a first direction and configured to clamp a first edge of a first mask sheet, and to position a second edge of the first mask sheet, which is opposite to the first edge, over the opening;
a sensor configured to sense the second edge of the first mask sheet; and
a controller configured to align the first mask sheet by adjusting the first clamps based on information regarding the second edge from the sensor.

2. The mask assembly manufacturing apparatus of claim 1, wherein the clamp unit further comprises second clamps arranged in a second direction, which is different from the first direction, and configured to clamp a third edge of the first mask sheet between the first edge and the second edge.

3. The mask assembly manufacturing apparatus of claim 2, wherein the controller is further configured to align the first mask sheet by adjusting the first clamps in the second direction and maintaining positions of the second clamps in the first direction.

4. The mask assembly manufacturing apparatus of claim 1, wherein the controller is further configured to move the clamp unit upwardly and downwardly.

5. The mask assembly manufacturing apparatus of claim 1, wherein one of the first clamps is on a first imaginary line extending between adjacent deposition openings in the first mask sheet.

6. The mask assembly manufacturing apparatus of claim 5, wherein the controller is further configured to adjust the first clamps based on a position of a point at which the second edge of the first mask sheet crosses the first imaginary line.

7. The mask assembly manufacturing apparatus of claim 1, wherein the clamp unit is configured to place a second mask sheet adjacent to the first mask sheet while clamping the second mask sheet using second clamps.

8. The mask assembly manufacturing apparatus of claim 7, wherein the controller is further configured to adjust the first clamps based on a separation distance between the second mask sheet and the second edge of the first mask sheet.

9. The mask assembly manufacturing apparatus of claim 7, further comprising a welder configured to weld and connect the second edge of the first mask sheet to the second mask sheet.

10. The mask assembly manufacturing apparatus of claim 1, further comprising a supporter positioned between the clamp unit and the opening of the mask frame.

11. A mask assembly manufacturing apparatus comprising:
a mask stage for seating thereon a mask frame defining an opening;
a clamp unit at one side of the mask stage, and comprising first clamps arranged in a first direction and configured to clamp a first edge of a first mask sheet;
a sensor configured to sense a second edge of the first mask sheet that is joined to a second mask sheet adjacent to the first mask sheet in a second direction; and
a controller configured to apply a compressive force to the first mask sheet by adjusting the first clamps based on information regarding the second edge.

12. The mask assembly manufacturing apparatus of claim 11, wherein the controller is further configured to detect a separation distance between the second mask sheet and the second edge of the first mask sheet as the information.

13. The mask assembly manufacturing apparatus of claim 12, wherein the controller is further configured to apply the compressive force to the first mask sheet in the second direction by moving the first clamps in the second direction based on the separation distance.

14. The mask assembly manufacturing apparatus of claim 12, wherein the controller is further configured to move one region of the first mask sheet toward the second mask sheet by moving the first clamps in the second direction based on the separation distance.

15. The mask assembly manufacturing apparatus of claim 11, wherein the first clamps comprise a first-a clamp and a first-b clamp, and
wherein the controller is further configured to move the first-a clamp and the first-b clamp using a first point of the second edge corresponding to the first-a clamp and a second point of the second edge corresponding to the first-b clamp.

16. The mask assembly manufacturing apparatus of claim 15, wherein the first point is on the second edge crossing a first imaginary line extending in the second direction and that passes through the first-a clamp, and
wherein the second point is on the second edge crossing another first imaginary line extending in the second direction and that passes through the first-b clamp.

17. The mask assembly manufacturing apparatus of claim 16, wherein the first imaginary line extends between adjacent deposition openings in the first mask sheet.

18. The mask assembly manufacturing apparatus of claim 11, wherein the clamp unit further comprises second clamps arranged in the second direction, and configured to clamp a third edge of the first mask sheet between the first edge and the second edge.

19. The mask assembly manufacturing apparatus of claim 18, wherein the controller is further configured to align a position of the first mask sheet by adjusting the first clamps in the second direction while maintaining positions of the second clamps in the first direction.

20. The mask assembly manufacturing apparatus of claim 11, further comprising a welder configured to weld and connect the second edge of the first mask sheet to the second mask sheet.
